(19) United States
(12) Patent Application Publication
(10) Pub. No.: US 2025/0174922 A1
(43) Pub. Date: May 29, 2025

(54) DAMPING ELEMENTS FOR PIN VIBRATION FRETTING RISK MITIGATION

(71) Applicant: Intel Corporation, Santa Clara, CA (US)

(72) Inventors: Phil GENG, Washougal, WA (US); Jeffory SMALLEY, East Olympia, WA (US); Steven A. KLEIN, Chandler, AZ (US); Baris BICEN, Chandler, AZ (US); Sanjoy SAHA, Portland, OR (US)

(21) Appl. No.: 18/522,051

(22) Filed: Nov. 28, 2023

(51) Int. Cl. H01R 12/71; H01L 23/498; H01R 13/24; H01R 13/405

(52) U.S. Cl. CPC H01R 12/714; H01L 23/49833; H01R 13/2435; H01R 13/405

(57) ABSTRACT

Embodiments disclosed herein include an apparatus for socket interconnects. In an embodiment, the apparatus comprises a substrate with a first surface and a second surface opposite from the first surface. In an embodiment, a first pin extends from the first surface, and a second pin extends from the second surface. In an embodiment, a first pad is on the first surface, where the first pad is electrically insulating. In an embodiment, a second pad is on the second surface, where the second pad is electrically insulating.

### BACKGROUND

In electronics packaging, socket based architectures are of growing importance due to their improvements in electrical performance and interconnect density. A socket substrate includes pins that extend up from a surface and contact pads on the surface of an opposing substrate (e.g., a package substrate). Typically, a compression or loading mechanism is used in order to deflect the pins so that they apply a substantially constant force against the opposing pad. This allows for consistent electrical contact between the components.

However, this constant force and direct contact can cause reliability issues. Particularly, during shipping and other transport, vibrations may result in the pins wiping across the pads. This can lead to scratching or other damage to the surface coating of the pads. Typically, the surface coating is an inert coating (such as gold) that prevents oxidation. When the surface coating is scratched away, the underlying material (such as nickel, copper, or the like) is exposed to environmental conditions (e.g., moisture, air, etc.). The underlying material can oxidize, which may render the exposed portion electrically non-conducting (or significantly reduce electrical conductivity). As such, issues with electrical opens may arise between the socket device and the overlying package substrate.

### BRIEF DESCRIPTION OF THE DRAWINGS

FIG. 1 is a cross-sectional illustration of an electronic system with a single sided socket between the board and the package substrate that includes a damping solution between the heatsink and the board, in accordance with an embodiment.

FIG. 2 is a cross-sectional illustration of a double sided socket that is provided between a board and a package substrate, in accordance with an embodiment.

FIG. 3A is a cross-sectional illustration of a portion of a socket interfacing with a pad that has a surface coating, in accordance with an embodiment.

FIG. 3B is a cross-sectional illustration of a portion of the socket after the pad has scratched away a portion of the surface coating, in accordance with an embodiment.

FIG. 4A is a cross-sectional illustration of a socket with a damping element on a top surface of the socket substrate, in accordance with an embodiment.

FIG. 4B is a cross-sectional illustration of a socket with damping elements on a top surface and a bottom surface of the socket substrate, in accordance with an embodiment.

FIG. 4C is a cross-sectional illustration of a socket with multiple damping elements on the top surface and the bottom surface of the socket substrate, in accordance with an embodiment.

FIG. 5A is a cross-sectional illustration of a damping element that is attached to the socket substrate by an adhesive, in accordance with an embodiment.

FIG. 5B is a cross-sectional illustration of a pair of damping elements that are aligned with each other and attached to the socket substrate by adhesives, in accordance with an embodiment.

FIG. 5C is a cross-sectional illustration of a damping element that is inserted in a hole that passes through a thickness of the socket substrate, in accordance with an embodiment.

FIG. 5D is a cross-sectional illustration of a pair of damping elements on opposite surfaces of the socket substrate that are offset from each other, in accordance with an embodiment.

FIG. 5E is a cross-sectional illustration of a first damping element that passes through the socket substrate and a second damping element attached to the socket substrate by an adhesive, in accordance with an embodiment.

FIG. 5F is a cross-sectional illustration of a damping element over the socket substrate and a standoff feature under the damping element on the opposite surface of the socket substrate, in accordance with an embodiment.

FIG. 6A is a plan view illustration of a socket with an array of rectangular damping elements around a perimeter of the socket, in accordance with an embodiment.

FIG. 6B is a plan view illustration of a socket with rectangular and circular damping elements around a perimeter of the socket, in accordance with an embodiment.

FIG. 6C is a plan view illustration of a socket with damping elements around a perimeter of the socket and damping elements within the pin field, in accordance with an embodiment.

FIG. 7 is a plan view illustration of a socket with a frame with damping elements on the frame and the socket, in accordance with an embodiment.

FIG. 8A is a cross-sectional illustration of a socket between substrates with damping elements, in accordance with an embodiment.

FIG. 8B is a cross-sectional illustration of a socket between substrates with damping elements and a standoff feature, in accordance with an embodiment.

FIG. 9 is a cross-sectional illustration of an electronic system with a socket between the board and package substrate that includes damping elements to protect pads from vibrational damage, in accordance with an embodiment.

FIG. 10 is a schematic of a computing device built in accordance with an embodiment.

### EMBODIMENTS OF THE PRESENT DISCLOSURE

Described herein are electronic systems, and more particularly, damping elements for use in socket designs in order to mitigate fretting risk of pad surfaces, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

As noted above, socket based interconnect solutions have electrical and performance benefits. However, the interaction between the pins and the opposing pads can lead to surface coating removal. This then allows for corrosion of the pads, which may generate an electrical open. The scratching of the coating is particularly problematic during transportation and/or movement of the electronic system. Vibration that occurs during such operations can lead to the swaying or brushing of the pins against the pads. Accordingly, solutions for mitigating vibration are desirable in order to improve reliability of the electronic system.

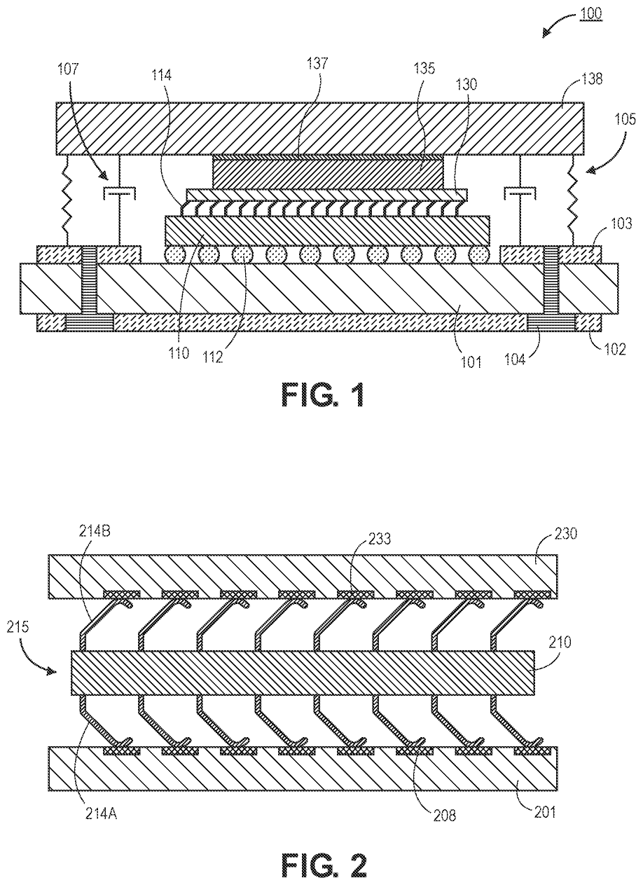

Referring now to FIG. 1, a cross-sectional illustration of an electronic system 100 is shown, in accordance with an embodiment. The electronic system 100 includes a socket based coupling between the board 101 and the package substrate 130. Accordingly, vibrational forces may result in scratching of pads and lead to corrosion. As such a vibrational damping solution is provided.

In an embodiment, the electronic system 100 includes a board 101, such as a printed circuit board (PCB), a motherboard, or the like. The board 101 is typically an organic dielectric material that may include fiber reinforcement (e.g., glass fiber reinforcement). In an embodiment, a back plate 102 may be provided on the backside of the board 101, and a bolster plate 103 may be provided on the front side of the board 101. A pin 104 may pass through the board 101 to secure the back plate 102 and the bolster plate 103 to the board 101.

In an embodiment, a socket may be provided between the board 101 and a package substrate 130. The socket may include a socket substrate 110. The socket substrate 110 may include any type of substrate, such as an organic dielectric, or the like. Electrically conductive routing (not shown) may pass through a thickness of the socket substrate 110. In an embodiment, the bottom of the socket substrate 110 may be coupled to the board 101 through interconnects 112, such as solder balls or the like. Pins 114 may extend up from the top surface of the socket substrate 110 to provide a connection to the package substrate 130. The pins 114 may land on pads (not shown) on the package substrate 130. That is, in the embodiment shown in FIG. 1, the socket is a single sided socket system with pins 114 only on one side of the socket substrate 110. Such a system may sometimes be referred to as a land grid array (LGA) socket system.

In an embodiment, a die 135 is coupled to the package substrate 130. The die 135 may be coupled to the package substrate 130 through any suitable first level interconnect (FLI) architecture (not shown), such as solder balls, copper bumps, hybrid bonding, or the like. The die 135 may be a processor, or the like. In an embodiment, a thermal interface material (TIM) 137 may couple the top of the die 135 to a heatsink 138. The heatsink 138 may be mechanically coupled to the board 101 through a retention mechanism 105 (illustrated schematically in FIG. 1). The retention mechanism 105 may include one or more of pins, springs, clips, clamps, screws, bolts, or the like. The retention mechanism 105 compresses the heatsink 138 down towards the board 101 and compresses the pins 114 against the pads on the package substrate 130.

Despite being mechanically compressed against the package substrate 130, the pins 114 may still suffer from vibrational forces, such as those described above. As such, the pins 114 may scratch and/or damage the opposing pads on the package substrate 130. To minimize this, a damping feature 107 may be used. The damping feature 107 in FIG. 1 couples the heatsink 138 to the board 101. The damping feature 107 may be a spring or a spring-like mechanism. Such a design is usually beneficial for global pin fretting (or scratching) mitigation. To address localized fretting (e.g., along edges, corners, or certain regions within the pin field), alternative solutions may be used.

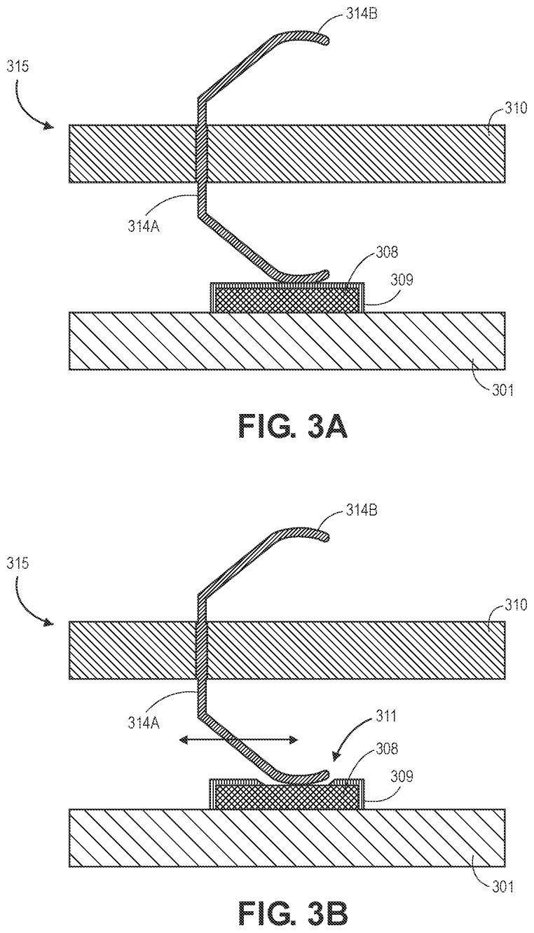

Referring now to FIG. 2, a cross-sectional illustration of a structure that includes a double sided socket 215 is shown, in accordance with an embodiment. In an embodiment, the socket 215 is sandwiched between a board 201 and a package substrate 230. The retention mechanism that compresses the socket 215 is omitted for simplicity. The board 201 may be a PCB, motherboard, or the like. The package substrate 230 may be any suitable package substrate structure with or without a core (e.g., a glass core, an organic core, or the like).

In an embodiment, the socket 215 includes a socket substrate 210. First pins 214A may extend away from a bottom surface of the socket substrate 210, and second pins 214B may extend away from a top surface of the socket substrate 210. The first pins 214A may land on pads 208 of the board 201. The second pins 214B may land on pads 233 of the package substrate 230. The pins 214A and 214B are substantially similar to each other. In other embodiments, the first pins 214A may have a different shape or structure than the second pins 214B. Generally, the pins 214A and 214B are cantilevered structures. As the package substrate 230 is compressed towards the board 201, the pins 214A and 214B are bent back towards the socket substrate 210. The deflected (or loaded) pins 214A and 214B exert a force that presses against the pads 208 and 233. As such, consistent electrical connections or interconnects are provided between pads 208 and pads 233. Sockets 215 with such a double sided pin 214A and 214B arrangement may sometimes be referred to as a compression mount technology (CMT) socketing system.

Despite providing good connection between the pads 208 and 233, such CMT socket systems are also susceptible to fretting or scratching damage. Particularly, vibration based motion or other high frequency dynamic displacements of the system can cause damage. The fretting damage is generally exhibited or detected at the surfaces of the pads 208 and/or 233. For example, surface coatings may be scratched away. In some instances, the exposed underlayer may corrode, which negatively impacts electrical performance.

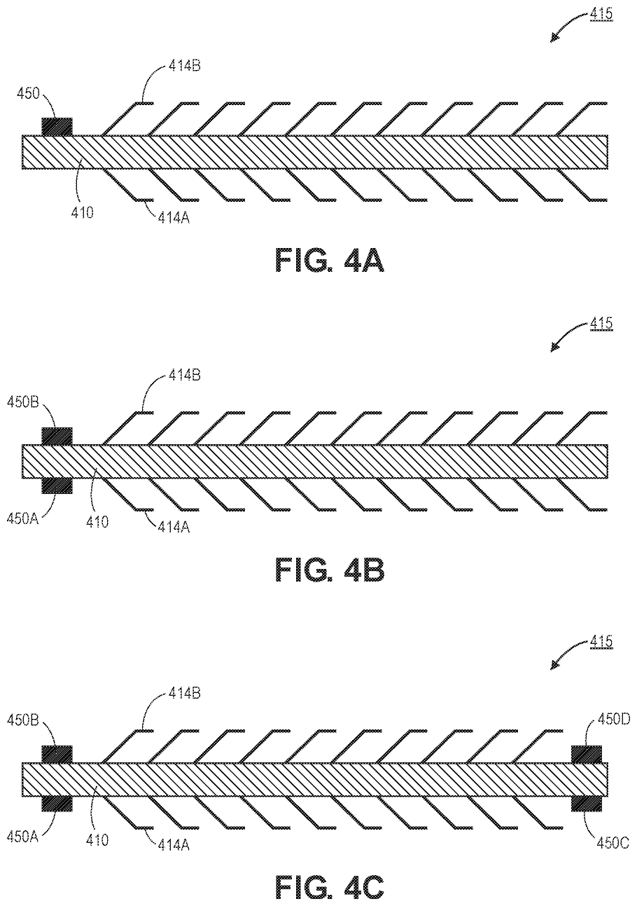

An example of such damage attributable to high frequency dynamic loading or vibration is shown in FIGS. 3A and 3B. Referring now to FIG. 3A, a cross-sectional illustration of a portion of an assembly is shown, in accordance with an embodiment. The assembly illustrated in FIG. 3A is zoomed in on a single pair of pins 314A (lower pin) and 314B (upper pin). A connection between the lower pin 314A and the upper pin 314B may be provided through the socket substrate 310. For example, an electrically conductive via, trace, and/or the like may be provided between pins 314A and 314B. The upper pin 314B is shown as floating (i.e., not pressed against a pad or substrate). Though, in practice an additional substrate will press down against the upper pin 314B to compress the socket 315.

In an embodiment, the lower pin 314A is compressed against a pad 308 on a lower substrate 301, such as a board. The pad 308 in FIG. 3A protrudes up from the top surface of the lower substrate 301. In other embodiments, the pad 308 may be flush with the top surface of the lower substrate 301. In an embodiment, the pad 308 may comprise any suitable electrically conductive material, such as, but not limited to, copper, nickel, aluminum, gold, platinum, and/or the like. In some instances, the material of the pad 308 may be susceptible to corrosion or oxidation if exposed to the environment (e.g., moisture, air, etc.). As such, a surface coating 309 may be applied over the pad 308 in order to protect the underlying pad 308. The surface coating 309 may be an electrically conductive material that is more resistant to corrosion, inert, and/or the like. For example, the surface coating 309 may comprise gold in some instances.

Referring now to FIG. 3B, a cross-sectional illustration of the assembly after some amount of vibration or other high frequency dynamic loading is shown, in accordance with an embodiment. As indicated by the double sided arrows, the lower pin 314A may be subject to cyclical displacement in a plane substantially parallel to a top surface of the lower substrate 301. Though, pin 314A may also displace vertically (up and down in FIG. 3B) due to vibration. The displacement of the pin 314A may result in fretting and/or scratching of the surface of the pad 308. Repeated fretting may result in the wearing away and/or removal of portions of the surface coating 309. For example, an opening 311 may be exposed around the bottom foot of the lower pin 314A. The opening 311 allows for moisture to access the underlying pad 308, and oxidation may form between the pad 308 and the foot of the lower pin 314A. Accordingly, an electrical open may be formed between the socket 315 and the lower substrate 301 and reliability of the device is negatively impacted.

As such, embodiments disclosed herein include the use of damping elements that are provided between the socket substrate and the overlying and/or underlying substrates. The damping elements (sometimes referred to as “pads”, “damping pads”, or the like) may be provided at locations susceptible to vibration induced fretting damage. For example, damping elements may be located close to an outer perimeter of the pin field, corners of the pin field, within the pin field, and/or any other region of the socket. The damping elements may be electrically non-conductive materials, substantially electrically insulating, or the like. The damping elements are configured to absorb energy delivered at high frequencies so that force that would normally move the pin is mitigated or completely negated. While dynamic load is absorbed, the damping elements do not take significant load to compress during static conditions. As such, the damping elements do not impact loading mechanism design at a platform level.

The damping elements may be any suitable shape or design. The damping elements can be designed to fit within critical areas of the pin field, so they fit proximate to edges of the socket substrate, or the like. Damping elements may be rectangular, circular, and/or any shape. Damping elements may include any material or materials that are suitable for absorbing the high frequency forces. For example, damping elements may comprise one or more of natural cork, artificial cork, felt, rubber, or the like.

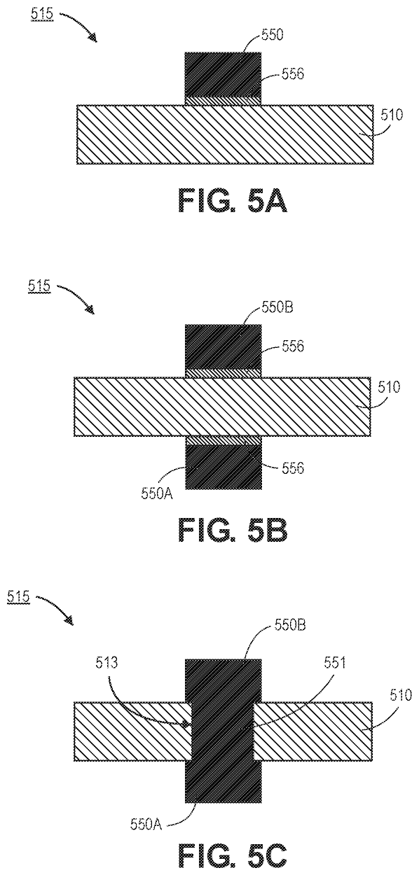

Referring now to FIGS. 4A-4C, a series of cross-sectional illustrations depicting a few socket 415 architectures is shown in accordance with an embodiment. The sockets 415 in FIGS. 4A-4C may each include one or more damping elements/pads 450.

Referring now to FIG. 4A, a cross-sectional illustration of a socket 415 is shown, in accordance with an embodiment. In an embodiment, the socket 415 may comprise a socket substrate 410. First pins 414A may extend out from a bottom surface of the socket substrate 410, and second pins 414B may extend out from a top surface of the socket substrate 410. The pins 414A and 414B may each have a cantilevered structure with a foot. The pins 414A and 414B are configured to be compressed against substrates (not shown). Each pin 414A may be electrically coupled to an individual pin 414B through vias or other electrical routing (not shown) in the socket substrate 410.

In an embodiment, a damping pad 450 may be provided on the top surface of the socket substrate 410. The damping pad 450 may have a height that is smaller than the standoff height of the pins 414B. Though, upon compression of the pins 414B the damping pad 450 may have the same or similar height as the pins 414B. In an embodiment, the damping pad 450 may have a height up to approximately 2.0 mm, up to approximately 1.0 mm, up to approximately 0.5 mm, or up to approximately 0.1 mm. Though, taller or shorter damping pads 450 may also be used in some embodiments. The damping pad 450 may have any area (when viewed from above), as well as any shape (e.g., rectangular, circular, etc.). The damping pad 450 may comprise one or more of natural cork, synthetic cork, felt, rubber, or the like. In the embodiment shown in FIG. 4A, the damping pad 450 is provided between an edge of the pin field and the edge of the socket substrate 410.

Referring now to FIG. 4B, a cross-sectional illustration of a socket 415 is shown, in accordance with an additional embodiment. In an embodiment, the socket 415 is provided with a first damping pad 450A on a bottom surface of the socket substrate 410 and a second damping pad 450B on a top surface of the socket substrate 410. The first damping pad 450A and the second damping pad 450B may be substantially similar to the damping pad 450 described with respect to FIG. 4A. In a particular embodiment, the first damping pad 450A is substantially similar to the second damping pad 450B. Though, in other embodiments, one or more of size, material composition, or any other attribute may be different between the first damping pad 450A and the second damping pad 450B.

In the particular embodiment shown in FIG. 4B, the first damping pad 450A is aligned with the second damping pad 450B. That is, a centerline of the first damping pad 450A may be substantially coincident with a centerline of the second damping pad 450B. In the case where the area of the first damping pad 450A is similar to the area of the second damping pad 450B, the edge surfaces of the two damping pads 450A and 450B may also be substantially aligned with each other.

Referring now to FIG. 4C, a cross-sectional illustration of a socket 415 is shown, in accordance with an additional embodiment. As shown, the socket 415 comprises a set of four damping pads 450A-450D. A first pair of damping pads 450A and 450B may be provided along one edge of the pin field (e.g., the left edge of FIG. 4C), and a second pair of damping pads 450C and 450D may be provided on an opposite edge of the pin field (e.g., the right edge of FIG. 4C). The first pair of damping pads 450A and 450B may be centered and aligned with each other, and the second pair of damping pads 450C and 450D may also be centered and aligned with each other. The damping pads 450A-450D may have structures, material compositions, and the like similar to any of the damping pads 450 described in greater detail herein.

In FIGS. 4A-4C, the damping pads 450 are illustrated as being outside of the pin fields. That is, the damping pads 450 are between the array of pins 414 and the edge of the socket substrate 410. However, in some embodiments, one or more damping pads 450 may also be provided within the pin fields. As such, one or more pins 414 may be position between a damping pad 450 and an edge of the socket substrate 410.

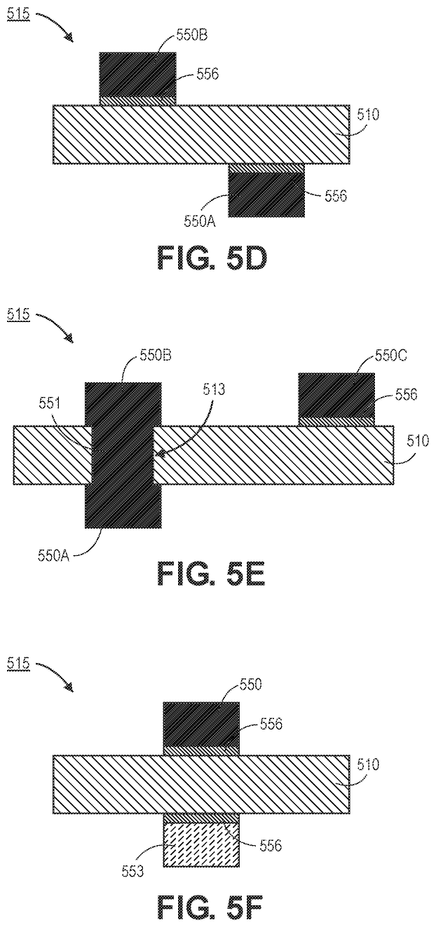

Referring now to FIGS. 5A-5F, a series of cross-sectional illustrations depicting a portion of a socket 515 is shown, in accordance with various embodiments. In the embodiments shown, only the region directly around the damping pads 550 is shown for simplicity. The pins (above and below) the socket substrate 510 are omitted. The damping pads 550 in FIGS. 5A-5F may be positioned at any location along the socket substrate 510 (e.g., within the pin field, at the edge of the pin field, or the like).

Referring now to FIG. 5A, a cross-sectional illustration of a portion of a socket 515 is shown, in accordance with an embodiment. In an embodiment, the socket 515 may include a socket substrate 510. A damping pad 550 may be provided over a top surface of the socket substrate 510. The damping pad 550 may be similar in structure, shape, and/or material composition as any of the damping pads described in greater detail herein. For example, the damping pad 550 may comprise natural cork, synthetic cork, felt, or rubber. In an embodiment, the damping pad 550 may be mechanically coupled to the socket substrate 510 by an adhesive 556. The adhesive 556 may comprise glue, tape, or the like. While the adhesive 556 is shown as being only between the damping pad 550 and the socket substrate 510, the adhesive 556 may extend past edges of the damping pad 550 or wrap up sidewalls of the damping pad 550. The relative thicknesses of the adhesive 556 and the damping pad 550 are illustrative. In some embodiments, the adhesive 556 may be thicker than the damping pad 550. While the damping pad 550 may provide a majority of the damping effect, the adhesive 556 may also provide some amount of damping.

Referring now to FIG. 5B, a cross-sectional illustration of a portion of a socket 515 is shown, in accordance with an additional embodiment. The socket 515 in FIG. 5B may be substantially similar to the socket 515 in FIG. 5A, with the addition of a second damping pad 550. For example, a first damping pad 550A may be provided over a bottom surface of the socket substrate 510, and a second damping pad 550B may be provided over a top surface of the socket substrate 510. Both the first damping pad 550A and the second damping pad 550B may be adhered to the socket substrate 510 by an adhesive 556. The first and second damping pads 550A and 550B, and the adhesive 556 may be similar to the damping pad 550 and adhesive 556 described with respect to FIG. 5A. In an embodiment, the first damping pad 550A may be centered and/or aligned with the second damping pad 550B.

Referring now to FIG. 5C, a cross-sectional illustration of a portion of a socket 515 is shown, in accordance with an additional embodiment. The socket 515 may comprise a first damping pad 550A and a second damping pad 550B. The first damping pad 550A may be mechanically coupled to the second damping pad 550B by a link 551 that passes through a hole 513 in the socket substrate 510. The first damping pad 550A, the link 551, and the second damping pad 550B may be a monolithic structure. For example, the combined structure may be press-fit through the hole 513. As such, there may not be a need for a glue or other adhesive in order to hold the damping pads 550A and 550B in place. In an embodiment, widths of the first damping pad 550A and the second damping pad 550B may both be greater than a width of the link 551. For example, the link 551 may have a width that is up to approximately 95% the width of one of the damping pads 550A or 550B, up to approximately 75% the width of one of the damping pads 550A or 550B, up to approximately 50% the width of one of the damping pads 550A or 550B, or up to approximately 20% the width of one of the damping pads 550A or 550B.

Referring now to FIG. 5D, a cross-sectional illustration of a portion of a socket 515 is shown, in accordance with an additional embodiment. The socket 515 in FIG. 5D may be similar to the socket 515 shown in FIG. 5B with the exception of the placement of the first damping pad 550A relative to the second damping pad 550B. Instead of being aligned and/or centered with each other, the first damping pad 550A is offset from the second damping pad 550B. In the particular embodiment shown in FIG. 5D, the first damping pad 550A is entirely outside of a shadow (or footprint) of the second damping pad 550B. Though, in some embodiments, the first damping pad 550A and the second damping pad 550B may at least partially overlap each other.

Referring now to FIG. 5E, a cross-sectional illustration of a portion of a socket 515 is shown, in accordance with an additional embodiment. The socket 515 in FIG. 5E may include a plurality of different damping pad 550 configurations. For example, a monolithic structure may be pressed through a hole 513 in the socket substrate 510 to form a first damping pad 550A that is coupled to a second damping pad 550B by a link 551. Additionally, a third damping pad 550C may be provided on the top surface of the socket substrate 510. For example, the third damping pad 550C may be coupled to the socket substrate 510 by an adhesive 556 or other fastening mechanism.

Referring now to FIG. 5F, a cross-sectional illustration of a portion of a socket 515 is shown, in accordance with yet another embodiment. The socket 515 may comprise a damping pad 550 on a top surface of the socket substrate 510. A standoff feature 553 may be provided on the opposite surface of the socket substrate 510. The standoff feature 553 may be a non-compressible, or substantially non-compressible material, such as a high elastic modulus material. The standoff feature 553 may be a rigid plastic, polymer, metallic, ceramic, glass, or the like. The standoff feature 553 may be attached to the socket substrate 510 through an adhesive 556 or other fastening mechanism. In an embodiment, the standoff feature 553 may provide a set standoff distance to prevent over compression of the socket 515. The standoff feature 553 may also improve force transfer through the socket 515 into the underlying board (not shown). The standoff feature 553 may be centered and/or aligned with a damping pad 550, or the standoff feature 553 may be offset from a damping pad 550.

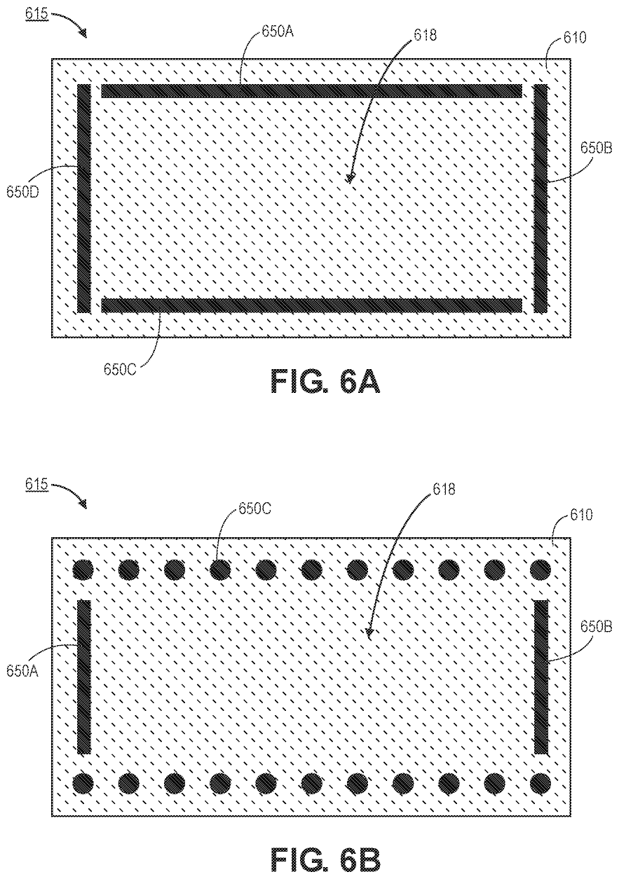

Referring now to FIGS. 6A-6C, a series of plan view illustrations depicting top surfaces of sockets 615 is shown, in accordance with various embodiments. The sockets 615 are depicted without the pins being present. However, it is to be appreciated that an array of pins (e.g., similar to any of the pins described in greater detail herein) may be provided in an array in a central region 618 of the socket substrate 610.

Referring now to FIG. 6A, a plan view illustration of a socket 615 is shown, in accordance with an embodiment. As shown, a plurality of damping pads 650A-650D may be provided on the top surface of the socket substrate 610. The damping pads 650A-650D may be elongated rectangular shapes. The damping pads 650A-650D may substantially encircle an outer perimeter of the pin field 618. In an embodiment, each damping pad 650A, 650B, 650C, and 650D may generally be provided along (and proximate) to one of the edges of the socket substrate 610.

Referring now to FIG. 6B, a plan view illustration of a socket 615 is shown, in accordance with an additional embodiment. In FIG. 6B, damping pads 650A and 650B may be rectangular shapes that extend along edges of the socket substrate 610. The damping pads 650C may be circular pads that are positioned in a line along an edge of the socket substrate 610. That is, the damping pads 650A-650C may have different shapes in some embodiments.

Referring now to FIG. 6C, a plan view illustration of a socket 615 is shown, in accordance with an additional embodiment. The socket 615 in FIG. 6C is substantially similar to the socket 615 in FIG. 6B, with the addition of damping pads 650D. The damping pads 650D may be positioned within the pin field 618. The damping pads 650D may also be circular, but the damping pads 650D may have a diameter that is different than the diameter of damping pads 650C. Though, damping pads 650D may take any suitable shape in order to fit within the pins of the pin field 618.

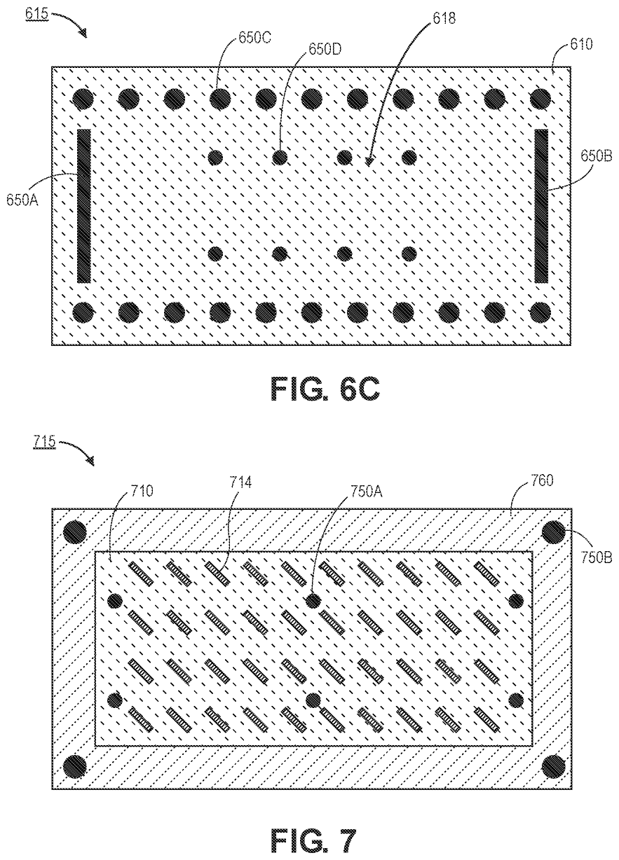

Referring now to FIG. 7, a plan view illustration of a socket 715 is shown, in accordance with an additional embodiment. The socket 715 may comprise a socket substrate 710 that is surrounded by a frame 760. The frame 760 may be a metallic frame or any other suitable material. In an embodiment, damping pads 750A may be provided amidst the pins 714 of the socket substrate 710. Additionally, damping pads 750B may be provided on the frame 760. The size, shape, material, and/or structure of damping pads 750A and 750B may be similar to any of the damping pads described in greater detail herein.

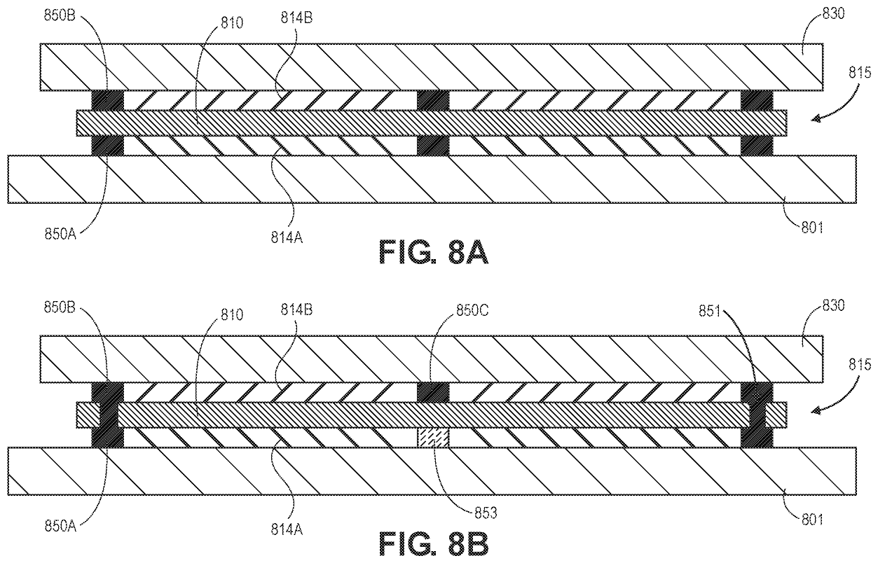

Referring now to FIGS. 8A and 8B, cross-sectional illustrations depicting loaded sockets 815 between substrates 801 and 830 are shown, in accordance with additional embodiments.

In FIG. 8A, the socket 815 is provided between a board 801 and a package substrate 830. The socket 815 may comprise a socket substrate 810. First pins 814A may extend from a bottom of the socket substrate 810 towards the board 801, and second pins 814B may extend from a top of the socket substrate 810 to the package substrate 830. In an embodiment, damping pads 850A may be provided between the socket substrate 810 and the board 801, and damping pads 850B may be provided between the socket substrate 810 the package substrate 830. The damping pads 850A may directly contact the board 801 (e.g., contacting board 801 layers, board 801 solder resist, or any other layers at the top of the board 801) and the socket substrate 810. Similarly, damping pads 850B may directly contact the package substrate 830 (e.g., contacting package substrate 830 layers, package substrate 830 solder resist, or any other layers at the bottom of the package substrate 830) and the socket substrate 810. In an embodiment, the damping pads 850A and 850B may be at least partially compressed. That is, a height of the damping pads 850A and 850B may be smaller than a height if no external forces were applied to the top and bottom surfaces of the damping pads 850A and 850B. In an embodiment, a number of damping pads 850A may be equal to a number of damping pads 850B. Though, in other embodiments the number of damping pads 850A may be different than the number of damping pads 850B. The damping pads 850A and 850B may be similar to any of the damping pads described in greater detail herein. The damping pads 850A and 850B may be positioned outside of the pin field, within the pin field, or at any other location on the socket substrate 810.

In FIG. 8B, the socket 815 is similar to the one shown in FIG. 8A, with the exception of the structure of the damping pads 850. For example, damping pads 850A and 850B may be coupled together by a link 851 that passes through the socket substrate 810. Additionally, the damping pad 850C may be provided over a standoff feature 853 instead of another damping pad 850. Further, while damping pads 850 in FIGS. 8A and 8B are substantially aligned and centered with each other, embodiments are not so limited. In some instances, damping pads 850 may be offset from each other, similar to some embodiments described in greater detail above.

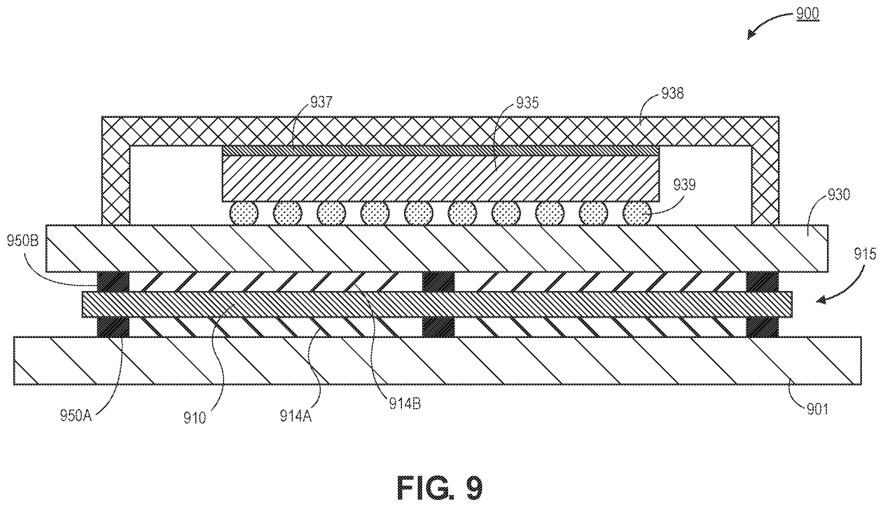

Referring now to FIG. 9, a cross-sectional illustration of an electronic system 900 is shown, in accordance with an embodiment. In an embodiment, the electronic system 900 comprises a board 901, such as a PCB, a motherboard, or the like. The board 901 may be coupled to a package substrate 930 by a socket 915. In an embodiment, the socket 915 is a CMT socket or a double sided socket 915. That is, pins 914A may be provided between socket substrate 910 and the board 901, and pins 914B may be provided between socket substrate 910 and the package substrate 930.

In an embodiment, damping pads 950A and 950B may be provided between the socket 915 and the board 901 or package substrate 930. In an embodiment, the damping pads 950A and 950B may be similar to any of the damping pad architectures described in greater detail herein. For example, damping pads 950A and 950B may have any size, shape, structure, location along the socket substrate 910 (e.g., within the pin field, outside the pin field, etc.), material composition (e.g., natural cork, synthetic cork, felt, rubber, etc.), alignment, or the like. The damping pads 950A and 950B may be configured to mitigate fretting damage to pads (not shown) on the board 901 and/or the package substrate 930.

In an embodiment, a die 935 may be coupled to the package substrate 930 by interconnects 939. Interconnects 939 may be any suitable FLI architecture. In an embodiment, the die 935 may be a central processing unit (CPU), a graphics processing unit (GPU), an XPU, a communications die, a memory die, or the like. In an embodiment, a plurality of dies 935 may be coupled to the package substrate 930. Two or more dies 935 may be communicatively coupled together by a bridge (not shown), such as one embedded in the package substrate 930. In an embodiment, a heat sink and/or integrated heat spreader (IHS) 938 is thermally coupled to the die 935 through a TIM 937.

In an embodiment, a loading mechanism (not shown) is used to compress or load the socket 915. The loading mechanism may apply a force that pushes the package substrate 930 and the board 901 towards each other in order to compress the pins 914A and 914B. The loading mechanism may include any suitable fastening architecture, such as a clamp, a screw, a bolt, a spring, a pin, or the like.

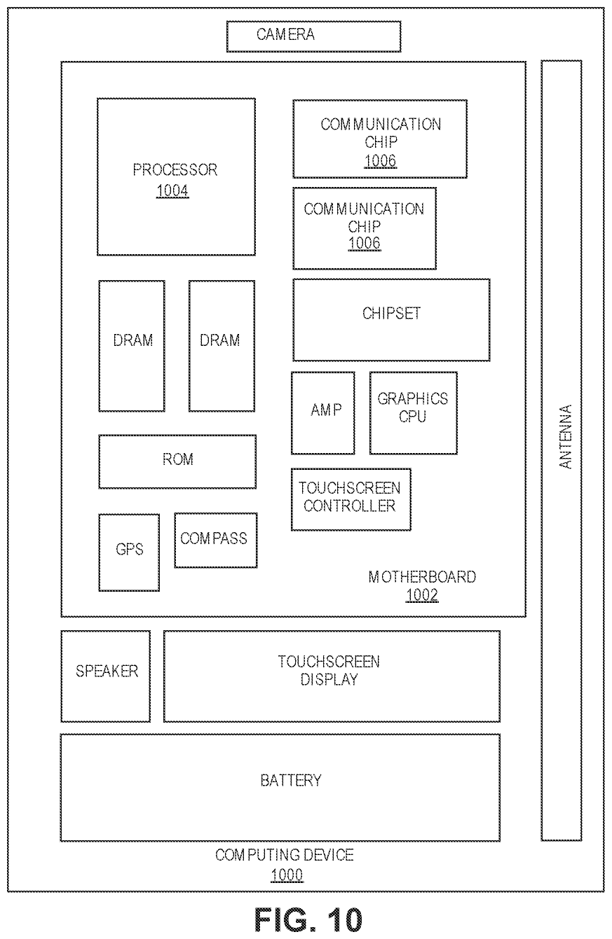

FIG. 10 illustrates a computing device 1000 in accordance with one implementation of the disclosure. The computing device 1000 houses a board 1002. The board 1002 may include a number of components, including but not limited to a processor 1004 and at least one communication chip 1006. The processor 1004 is physically and electrically coupled to the board 1002. In some implementations the at least one communication chip 1006 is also physically and electrically coupled to the board 1002. In further implementations, the communication chip 1006 is part of the processor 1004.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 1006 enables wireless communications for the transfer of data to and from the computing device 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing device 1000 includes an integrated circuit die packaged within the processor 1004. In some implementations of the disclosure, the integrated circuit die of the processor may be part of an electronic package that includes a CMT socket with one or more vibration damping pads that are configured to mitigate localized fretting in order to maintain pad surface coating integrity, in accordance with embodiments described herein. The term “processor” may refer to any device or portion of a device that processes electronic data from registers and/or memory to transform that electronic data into other electronic data that may be stored in registers and/or memory.

The communication chip 1006 also includes an integrated circuit die packaged within the communication chip 1006. In accordance with another implementation of the disclosure, the integrated circuit die of the communication chip may be part of an electronic package that includes a CMT socket with one or more vibration damping pads that are configured to mitigate localized fretting in order to maintain pad surface coating integrity, in accordance with embodiments described herein.

In an embodiment, the computing device 1000 may be part of any apparatus. For example, the computing device may be part of a personal computer, a server, a mobile device, a tablet, an automobile, or the like. That is, the computing device 1000 is not limited to being used for any particular type of system, and the computing device 1000 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: an apparatus, comprising: a substrate with a first surface and a second surface opposite from the first surface; a first pin that extends from the first surface; a second pin that extends from the second surface; a first pad on the first surface, wherein the first pad is electrically insulating; and a second pad on the second surface, wherein the second pad is electrically insulating.

Example 2: the apparatus of Example 1, wherein the first pad is positioned directly over and aligned with the second pad.

Example 3: the apparatus of Example 2, wherein the first pad is coupled to the second pad by a link that passes through a hole in the substrate.

Example 4: the apparatus of Examples 1-3, wherein a centerline of the first pad is offset from a centerline of the second pad.

Example 5: the apparatus of Examples 1-4, wherein the first pad is adhered to the first surface by an adhesive.

Example 6: the apparatus of Examples 1-5, wherein the first pad and the second pad comprise natural cork, synthetic cork, felt, or rubber.

Example 7: the apparatus of Examples 1-6, wherein the first pad and the second pad comprise different materials.

Example 8: the apparatus of Examples 1-7, wherein the first pad has a rectangular shape when viewed from above.

Example 9: the apparatus of Examples 1-8, wherein the first pad has a circular shape when viewed from above.

Example 10: the apparatus of Examples 1-9, wherein a height of the first pin is greater than a height of the first pad.

Example 11: an apparatus, comprising: a board; a package substrate over the board; a socket between the board and the package substrate, wherein the socket comprises: a socket substrate; first pins between the socket substrate and the board; and second pins between the socket substrate and the package substrate; and first pads between the socket substrate and the board, wherein surfaces of the first pads directly contact the board; and second pads between the socket substrate and the package substrate, wherein surfaces of the second pads directly contact the package substrate.

Example 12: the apparatus of Example 11, wherein the first pads and the second pads comprise natural cork, synthetic cork, felt, or rubber.

Example 13: the apparatus of Example 11 or Example 12, wherein each first pad is aligned over a different one of the second pads.

Example 14: the apparatus of Examples 11-13, wherein the first pads comprise a different material than the second pads.

Example 15: the apparatus of Examples 11-14, wherein the first pads are attached to the socket substrate by an adhesive.

Example 16: the apparatus of Examples 11-15, wherein the first pads are arranged around a perimeter of an area comprising the first pins.

Example 17: an apparatus, comprising: a board; a package substrate over the board; a socket between the board and the package substrate, wherein the socket has double sided pins; first pads between the socket and the board, wherein the first pads are at least partially compressed; second pads between the socket and the package substrate, wherein the second pads are at least partially compressed; and a die coupled to the package substrate.

Example 18: the apparatus of Example 17, wherein the first pads and the second pads comprise natural cork, synthetic cork, felt, or rubber.

Example 19: the apparatus of Example 17 or Example 18, wherein a number of first pads is equal to a number of second pads.

Example 20: the apparatus of Examples 17-19, wherein the apparatus is part of a personal computer, a server, a mobile device, a tablet, or an automobile.

What is claimed is:

1. An apparatus, comprising:
a substrate with a first surface and a second surface opposite from the first surface;
a first pin that extends from the first surface;
a second pin that extends from the second surface;
a first pad on the first surface, wherein the first pad is electrically insulating; and
a second pad on the second surface, wherein the second pad is electrically insulating.

2. The apparatus of claim 1, wherein the first pad is positioned directly over and aligned with the second pad.

3. The apparatus of claim 2, wherein the first pad is coupled to the second pad by a link that passes through a hole in the substrate.

4. The apparatus of claim 1, wherein a centerline of the first pad is offset from a centerline of the second pad.

5. The apparatus of claim 1, wherein the first pad is adhered to the first surface by an adhesive.

6. The apparatus of claim 1, wherein the first pad and the second pad comprise natural cork, synthetic cork, felt, or rubber.

7. The apparatus of claim 1, wherein the first pad and the second pad comprise different materials.

8. The apparatus of claim 1, wherein the first pad has a rectangular shape when viewed from above.

9. The apparatus of claim 1, wherein the first pad has a circular shape when viewed from above.

10. The apparatus of claim 1, wherein a height of the first pin is greater than a height of the first pad.

11. An apparatus, comprising:
a board;
a package substrate over the board;
a socket between the board and the package substrate, wherein the socket comprises:
a socket substrate;
first pins between the socket substrate and the board; and
second pins between the socket substrate and the package substrate; and
first pads between the socket substrate and the board, wherein surfaces of the first pads directly contact the board; and
second pads between the socket substrate and the package substrate, wherein surfaces of the second pads directly contact the package substrate.

12. The apparatus of claim 11, wherein the first pads and the second pads comprise natural cork, synthetic cork, felt, or rubber.

13. The apparatus of claim 11, wherein each first pad is aligned over a different one of the second pads.

14. The apparatus of claim 11, wherein the first pads comprise a different material than the second pads.

15. The apparatus of claim 11, wherein the first pads are attached to the socket substrate by an adhesive.

16. The apparatus of claim 11, wherein the first pads are arranged around a perimeter of an area comprising the first pins.

17. An apparatus, comprising:
a board;
a package substrate over the board;
a socket between the board and the package substrate, wherein the socket has double sided pins;
first pads between the socket and the board, wherein the first pads are at least partially compressed;
second pads between the socket and the package substrate, wherein the second pads are at least partially compressed; and
a die coupled to the package substrate.

18. The apparatus of claim 17, wherein the first pads and the second pads comprise natural cork, synthetic cork, felt, or rubber.

19. The apparatus of claim 17, wherein a number of first pads is equal to a number of second pads.

20. The apparatus of claim 17, wherein the apparatus is part of a personal computer, a server, a mobile device, a tablet, or an automobile.
